(19) United States
(12) Patent Application Publication
(10) Pub. No.: US 2024/0363375 A1
(43) Pub. Date: Oct. 31, 2024

(54) SUBSTRATE PROCESSING APPARATUS AND SUBSTRATE PROCESSING METHOD

(71) Applicant: SCREEN Holdings Co., Ltd., Kyoto (JP)

(72) Inventors: Tomohiro UEMURA, Kyoto (JP); Kazuhiro SHOJI, Kyoto (JP); Ryotaro SHINOHARA, Kyoto (JP); Shuhei NEMOTO, Kyoto (JP)

(21) Appl. No.: 18/642,941

(22) Filed: Apr. 23, 2024

(30) Foreign Application Priority Data
Apr. 26, 2023 (JP) 2023-072076

(51) Int. Cl. H01L 21/67; G05B 19/4099

(52) U.S. Cl. CPC H01L 21/6708; G05B 19/4099; G05B 2219/45031

(57) ABSTRACT

In this invention, a substrate with a notch on its periphery is rotated and a processing fluid is discharged from a nozzle while the nozzle is moved outward from an outside of the substrate through an edge surface of the substrate to the maximum processing position, which is a predetermined bevel processing distance away from the edge surface, and then the nozzle is returned in the opposite direction of the outward movement. Operating conditions including a rotation of the substrate, a discharge of the processing liquid, and the movement of the nozzle are not fixed but are switched at an intermediate position between the end surface and the maximum processing position.

### CROSS REFERENCE TO RELATED APPLICATION

The disclosure of Japanese Patent Application No. 2023-072076 filed on Apr. 26, 2023 including specification, drawings and claims is incorporated herein by reference in its entirety.

### BACKGROUND OF THE INVENTION

### 1. Field of the Invention

This invention relates to a substrate processing technique for processing a substrate provided with a cut such as a notch or the like at a peripheral edge part thereof by supplying a processing liquid to the peripheral edge part of the substrate while rotating the substrate. Herein, the substrate includes a semiconductor wafer, a glass substrate for liquid crystal display, a glass substrate for plasma display, an optical disk substrate, a magnetic disk substrate, a magneto-optical disk substrate, a glass substrate for photomask, a substrate for solar battery, and the like (hereinafter, referred to simply as a “substrate”). Further, the processing includes an etching process.

### 2. Description of the Related Art

A substrate processing apparatus is well known, which performs a chemical liquid processing, a cleaning process, or the like on a substrate such as a semiconductor wafer or the like by supplying a processing liquid to a peripheral edge part of the substrate while rotating the substrate. In an apparatus disclosed in JP 6980457B2, for example, there is a possibility that a processing liquid which collides against a bevel part, to be thereby scattered, may become a source of particles since a nozzle is moved above the substrate while discharging the processing liquid. Then, by controlling the number of rotation of the substrate, it is intended to suppress occurrence of the particles.

### SUMMARY OF THE INVENTION

The above-described conventional techniques address the problem of scattering of the processing liquid at the bevel part. Then, a certain effect is confirmed on a substrate having no cut referred to as a so-called notch. As to a substrate having a notch, which is typified by a semiconductor wafer, however, enough effect is not necessarily produced.

This invention is intended to solve the above-described problem, and it is an object of this invention to effectively suppress occurrence of particles in the substrate processing technique for processing a substrate provided with a cut at a peripheral edge part thereof by supplying a processing liquid to the substrate.

One aspect of this invention is directed to a substrate processing apparatus. The apparatus comprises: a substrate holder configured to hold a substrate provided with a cut at part of a peripheral edge part thereof in a horizontal posture, being rotatable about an axis of rotation; a rotating part configured to rotate the substrate holder about the axis of rotation; a processing liquid supplier having a nozzle to discharge a processing liquid so as to supply the processing liquid to the peripheral edge part of the substrate; a nozzle mover configured to move the nozzle in a radial direction of the substrate; and a controller configured to control an operating condition of the rotating part, the processing liquid supplier and the nozzle mover so as to cause the nozzle to make an outward movement from the outside of the substrate through an end surface of the substrate to a maximum processing position and then make a return movement in a direction reverse to the outward movement while rotating the substrate and discharging the processing liquid from the nozzle, the maximum processing position being away from the end surface toward a center of the substrate by a predetermined bevel processing distance, wherein assuming that the amount of processing liquid discharged from the nozzle arrives at the cut per unit time during the nozzle movement is a cut-arrival amount and that a midpoint between the end surface and the maximum processing position in the radial direction of the substrate is an intermediate position, the controller switches the operating condition of at least one of the rotating part, the processing liquid supplier, and the nozzle mover at the intermediate position so that the cut-arrival amount during the nozzle movement between the end surface and the intermediate position becomes lower than the cut-arrival amount during the nozzle movement between the intermediate position and the maximum processing position.

Other aspect of the invention is a substrate processing method. The method comprises: (a) rotating a substrate provided with a cut at part of a peripheral edge part thereof in a horizontal posture about an axis of rotation; (b) causing a nozzle to make an outward movement from the outside of the substrate where the nozzle is being rotated, through an end surface of the substrate to a maximum processing position away from the end surface by a predetermined bevel processing distance while discharging a processing liquid from the nozzle; and (c) causing the nozzle to make a return movement in a direction reverse to the outward movement while keeping rotation of the substrate and discharging the processing liquid from the nozzle after the operation (b) wherein assuming that the amount of processing liquid which is discharged from the nozzle during movement of the nozzle and arrives at the cut per unit time is a cut-arrival amount and that a midpoint between the end surface and the maximum processing position in a radial direction of the substrate is an intermediate position, an operating condition on at least one of rotation of the substrate, discharge of the processing liquid, and movement of the nozzle is switched at the intermediate position so that the cut-arrival amount during the movement of the nozzle between the end surface and the intermediate position is lower than the cut-arrival amount during the movement of the nozzle between the intermediate position and the maximum processing position both in the operation (b) and the operation (c).

In the present invention having such a configuration, the nozzle which discharges the processing liquid is reciprocatingly moved with respect to the substrate which is being rotated, and the processing liquid is supplied to the peripheral edge part of the substrate. During this reciprocating movement, the nozzle crosses above the cut. At that time, the processing liquid discharged from the nozzle arrives at the cut, and as the cut-arrival amount (the amount of processing liquid which arrives at the cut) increases, the probability of occurrence of liquid splash increases and the amount of liquid splash also increases. Further, as it becomes nearer to the end surface of the substrate, the effect of the liquid splash becomes larger. Then, in the present invention, in consideration of these points, the operating conditions including the rotation of the substrate during the reciprocating movement of the nozzle, the discharge of the processing liquid, and the movement of the nozzle are not fixed but are switched at an intermediate position between the end surface and the maximum processing position. In more detail, the operating conditions are switched so that the cut-arrival amount may become lower than that during the movement of the nozzle between the intermediate position and the maximum processing position.

According to this invention, in the substrate processing technique for processing a substrate provided with a cut at a peripheral edge part thereof by supplying a processing liquid to the substrate, it becomes possible to effectively suppress occurrence of particles.

All of a plurality of constituent elements of each aspect of the present invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the present invention described above can be combined with some or all of technical features included in another aspect of the present invention described above to obtain one independent form of the present invention in order to solve some or all of the aforementioned problems or to achieve some or all of the effects described in this specification.

### BRIEF DESCRIPTION OF THE DRAWINGS

FIG. 1 is a plan view showing a schematic configuration of a substrate processing system equipped with a first embodiment of a substrate processing apparatus according to the present invention;

FIG. 2 is a diagram showing a configuration of the first embodiment of the substrate processing apparatus according to the present invention;

FIG. 3 is a plan view schematically showing a configuration of a substrate processing part installed on a base member;

FIG. 4 is a diagram showing a dimensional relationship of a substrate held on a spin chuck and a rotating cup;

FIG. 5 is a diagram partially showing a rotating cup and a fixed cup;

FIG. 6 is an external perspective view showing a configuration of an upper surface protecting/heating mechanism;

FIG. 7 is a sectional view of the upper surface protecting/heating mechanism shown in FIG. 6;

FIG. 8 is a perspective view showing a processing liquid discharge nozzle on an upper surface side equipped in a processing mechanism;

FIG. 9 is a diagram schematically showing the configuration and operation of a nozzle mover;

FIG. 10 is a diagram schematically showing an exemplary relation of a region to be subjected to a bevel processing, a notch, and a substrate end surface;

FIG. 11 is a timing chart of a pre-dispense processing and a bevel processing performed in the first embodiment of the substrate processing apparatus according to the present invention;

FIG. 12 is a timing chart of a pre-dispense processing and a bevel processing performed in a second embodiment of the substrate processing apparatus according to the present invention;

FIG. 13 is a timing chart of a pre-dispense processing and a bevel processing performed in a third embodiment of the substrate processing apparatus according to the present invention;

FIG. 14 is a timing chart of a pre-dispense processing and a bevel processing performed in a fourth embodiment of the substrate processing apparatus according to the present invention;

FIG. 15 is a timing chart of a pre-dispense processing and a bevel processing performed in a fifth embodiment of the substrate processing apparatus according to the present invention;

FIG. 16 is a timing chart of a pre-dispense processing and a bevel processing performed in a sixth embodiment of the substrate processing apparatus according to the present invention;

FIG. 17 is a timing chart of a pre-dispense processing and a bevel processing performed in a seventh embodiment of the substrate processing apparatus according to the present invention; and

FIG. 18 is a diagram schematically showing another exemplary relation of the region to be subjected to the bevel processing, the notch, and the end surface of the substrate.

### DETAILED DESCRIPTION OF THE PREFERRED EMBODIMENTS

### The First Embodiment

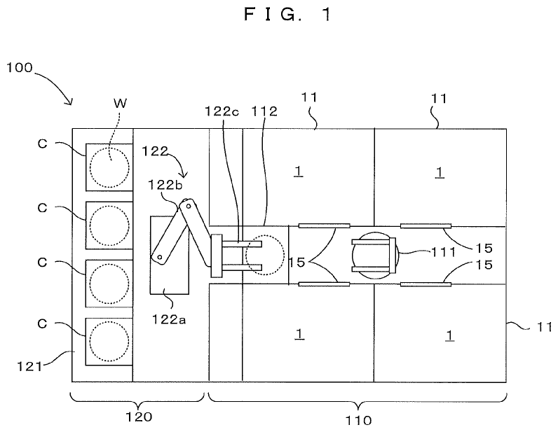

FIG. 1 is a plan view showing a schematic configuration of a substrate processing system equipped with a first embodiment of a substrate processing apparatus according to the present invention. This figure is a diagram not showing the external appearance of the apparatus, but showing an internal structure of a substrate processing system 100 by excluding an outer wall panel and other partial configurations. This substrate processing system 100 is, for example, a single-wafer type apparatus installed in a clean room and configured to process substrates W each having a circuit pattern (hereinafter, referred to as a “pattern”) only on one principal surface one by one. Then, substrate processing using a processing liquid is performed in a processing unit 1 equipped in the substrate processing system 100. In this specification, a pattern formation surface (one principal surface) formed with the pattern is referred to as a “front surface” and the other principal surface not formed with the pattern on an opposite side is referred to as a “back surface”. Further, a surface facing down is referred to as a “lower surface” and a surface facing up is referred to as an “upper surface”. Further, in this specification, the “pattern formation surface” means a surface of the substrate where an uneven pattern is formed in an arbitrary region.

Herein, various substrates such as semiconductor wafers, glass substrates for photomask, glass substrates for liquid crystal display, glass substrates for plasma display, substrates for FPD (Flat Panel Display), optical disk substrates, magnetic disk substrates and magneto-optical disk substrates can be applied as the “substrate” in the present embodiment. Although the substrate processing apparatus used in processing semiconductor wafers is mainly described as an example with reference to the drawings below, application to the processing of various substrates illustrated above is also possible.

As shown in FIG. 1, the substrate processing system 100 includes a substrate processing station 110 for processing the substrate W and an indexer station 120 coupled to this substrate processing station 110. The indexer station 120 includes a container holder 121 capable of holding a plurality of containers C for housing the substrates W (FOUPs (Front Opening Unified Pods), SMIF (Standard Mechanical Interface) pods, OCs (Open Cassettes) for housing a plurality of the substrates W in a sealed state), and an indexer robot 122 for taking out an unprocessed substrate W from the container C by accessing the container C held by the container holder 121 and housing a processed substrate W in the container C. A plurality of the substrates W are housed substantially in a horizontal posture in each container C.

The indexer robot 122 includes a base 122a fixed to apparatus housing, an articulated arm 122b provided rotatably about a vertical axis with respect to the base 122a, and a hand 122c mounted on the tip of the articulated arm 122b. The hand 122c is structured such that the substrate W can be placed and held on the upper surface thereof. Such an indexer robot including the articulated arm and the hand for holding the substrate is not described in detail since being known.

The substrate processing station 110 includes a mounting table 112 on which the indexer robot 122 places the substrate W, a substrate conveyor robot 111 arranged substantially in a center in a plan view and a plurality of processing units 1 arranged to surround this substrate conveyor robot 11. Specifically, the plurality of processing units 1 are arranged to face a space where the substrate conveyor robot 111 is arranged. The substrate conveyor robot 111 randomly accesses the mounting table 112 for these processing units 1 and transfers the substrate W to and from the mounting table 112. On the other hand, each processing unit 1 performs a predetermined processing to the substrate W, and corresponds to the substrate processing apparatus according to the present invention. In the present embodiment, these processing units (substrate processing apparatus) 1 have the same function. Thus, a plurality of the substrates W can be processed in parallel. If the substrate conveyor robot 111 can directly transfer the substrate W from the indexer robot 122, the mounting table 112 is not necessarily required.

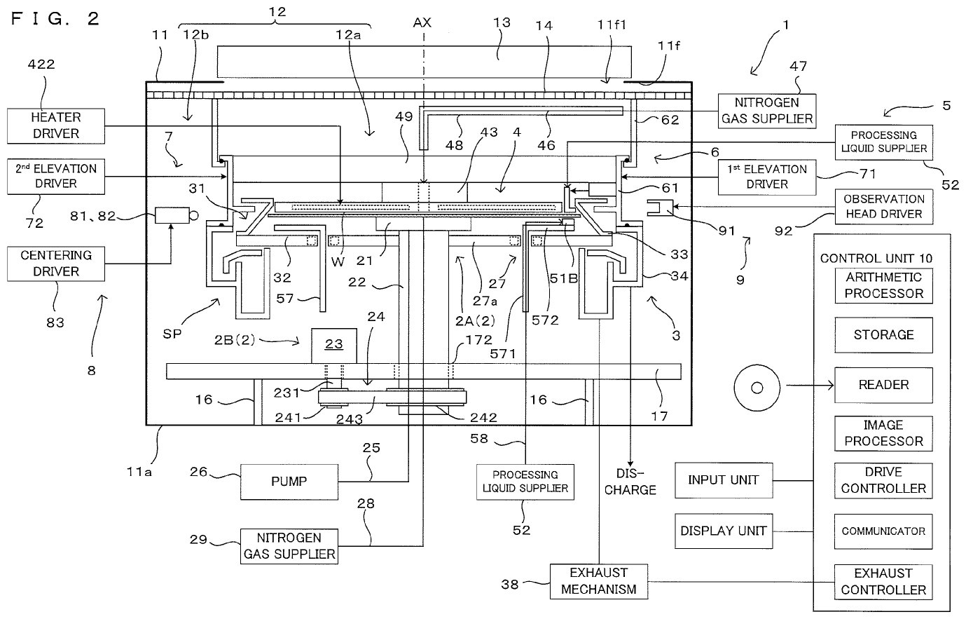

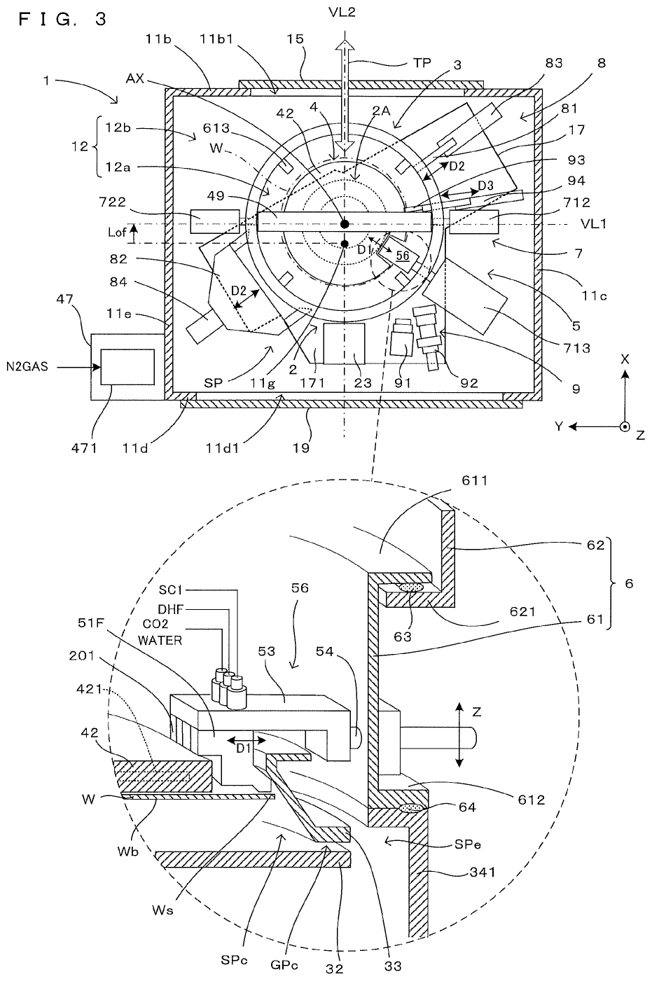

FIG. 2 is a diagram showing a configuration of the first embodiment of the substrate processing apparatus according to the present invention. FIG. 3 is a plan view of part of the substrate processing apparatus shown in FIG. 2 as viewed from above, and schematically shows a configuration of a substrate processing part installed on a base member. In FIGS. 2 and 3 and each figure to be referred to below, the dimensions and numbers of respective components may be shown in an exaggerated or simplified manner to facilitate understanding. As shown in FIG. 3, a chamber 11 used in the substrate processing apparatus (processing unit) 1 has a bottom wall 11a having a rectangular shape in a plan view vertically from above, four sidewalls 11b to 11e standing from a periphery of the bottom wall 11a, and a ceiling wall 11f covering respective upper end parts of the sidewalls 11b to 11e. By combining the bottom wall 11a, the sidewalls 11b to 11e, and the ceiling wall 11f, formed is an internal space 12 having a substantially rectangular shape.

On an upper surface of the bottom wall 11a, base support members 16 and 16 are fixed away from each other by fastener components such as bolts or the like. Specifically, the base support member 16 stands from the bottom wall 11a. On respective upper end parts of these base support members 16 and 16, a base member 17 is fixed by the fastener components such as bolts or the like. This base member 17 has a plane size smaller than that of the bottom wall 11a and is composed of a plate material having a thickness larger than that of the bottom wall 11a and rigidity higher than that thereof. As shown in FIG. 2, the base member 17 is raised by the base support members 16 and 16 from the bottom wall 11a vertically upward. In other words, a so-called raised floor structure is formed on a bottom part of the internal space 12 of the chamber 11. As described later, an upper surface of this base member 17 is finished to allow a substrate processing part SP for performing substrate processing on the substrate W to be installed thereon, and the substrate processing part SP is installed on the upper surface thereof. Components constituting this substrate processing part SP are electrically connected to a control unit 10 for controlling the entire apparatus and operate in response to commands from the control unit 10. Further, the shape of the base member 17 and the configuration and operation of the substrate processing part SP will be described in detail.

As shown in FIG. 2, a fan filter unit (FFU) 13 is attached to a ceiling wall 11f of the chamber 11. This fan filter unit 13 further cleans air in a clean room in which the substrate processing apparatus 1 is installed, and supplies the cleaned air into an internal space 12 of the chamber 11. The fan filter unit 13 includes a fan and a filter (e.g. a HEPA (High Efficiency Particulate Air) filter) for taking in the air in the clean room and feeding the air into the chamber 11, and feeds the cleaned air via an opening 11f1 provided in the ceiling wall 11f. In this way, a downflow of the cleaned air is formed in the internal space 12 in the chamber 11. Further, a punching plate 14 perforated with a multitude of air outlets is provided right below the ceiling wall 11f to uniformly disperse the cleaned air supplied from the fan filter unit 13.

In the substrate processing apparatus 1, a conveyance opening 11b1 is provided in the sidewall 11b facing the substrate conveyor robot 111 among the four sidewalls 11b to 11e, and the internal space 12 communicates with the outside of the chamber 11 therethrough. For this reason, a hand (not shown) of the substrate conveyor robot 111 can access the substrate processing part SP through the conveyance opening 11b1. In other words, by providing the conveyance opening 11b1, the substrate W can be loaded into or unloaded from the internal space 12. Further, a shutter 15 for opening and closing this conveyance opening 11b1 is attached to the sidewall 11b.

A shutter opening/closing mechanism (not shown) is connected to the shutter 15, and opens or closes the shutter 15 in response to an opening/closing command from the control unit 10. More specifically, in the substrate processing apparatus 1, the shutter opening/closing mechanism opens the shutter 15 in carrying an unprocessed substrate W into the chamber 11, and the unprocessed substrate W is carried in a face-up posture to the substrate processing part SP of the rotating mechanism 2 by a hand of a substrate conveyor robot 111. That is, the substrate W is placed on the spin chuck (denoted by 21 in FIG. 5) with an upper surface Wf facing up. If the hand of the substrate conveyor robot 111 is retracted from the chamber 11 after the substrate W is carried into, the shutter opening/closing mechanism closes the shutter 15. Then, a bevel processing is performed on the peripheral edge part Ws of the substrate W, as an example of a “substrate processing” of the present invention by the substrate processing part SP, in the processing space (equivalent to a sealed space SPs to be described in detail later) of the chamber 11. Further, after the bevel processing is finished, the shutter opening/closing mechanism opens the shutter 15 again and the hand of the substrate conveyor robot 111 carries out the processed substrate W from the substrate processing part SP. As just described, in the present embodiment, the internal space 12 of the chamber 11 is kept in a normal temperature atmosphere. Note that the “normal temperature” means a temperature in a range of 5° C. to 35° C. in this specification.

The sidewall 11d is positioned on the opposite side of the sidewall 11b with respect to the substrate processing part SP (FIG. 2) installed on the base member 17. In this sidewall 11d, provided is a maintenance opening 11d1. During maintenance, as shown in this figure, the maintenance opening 11d1 is opened. For this reason, an operator can access the substrate processing part SP through the maintenance opening 11d1 from the outside of the apparatus. On the other hand, during the substrate processing, a lid member 19 is so attached as to close the maintenance opening 11d1. Thus, in the present embodiment, the lid member 19 is detachable from the sidewall 11d.

Further, on an outer surface of the sidewall 11e, a nitrogen gas supplier 47 for supplying the substrate processing part SP with a heated inert gas (nitrogen gas in the present embodiment) is attached.

Thus, on the outer wall side of the chamber 11, the shutter 15, the lid member 19, and the nitrogen gas supplier 47 are arranged. In contrast to this, in an inner side of the chamber 11, i.e., in the internal space 12, the substrate processing part SP is installed on the upper surface of the base member 17 having the raised floor structure. Hereinafter, with reference to FIGS. 2 to 9, the configuration of the substrate processing part SP will be described.

In FIG. 3, the configuration of the substrate processing part installed on the base member is schematically shown. Hereinafter, for clarifying the arrangement relation and operation of the components of the apparatus, a coordinate system with a Z direction as a vertical direction and with an XY plane as a horizontal plane is shown as appropriate. In the coordinate system of FIG. 3, it is assumed that a horizontal direction in parallel to a conveyance path TP of the substrate W is an “X direction” and a horizontal direction orthogonal to the X direction is a “Y direction”. In more detail, directions from the internal space 12 of the chamber 11 toward the conveyance opening 11b1 and the maintenance opening 11d1 are referred to as a “+X direction” and a “−X direction”, respectively, directions from the internal space 12 of the chamber 11 toward the sidewalls 11c and 11e are referred to as a “−Y direction” and a “+Y direction”, respectively, and directions vertically upward and downward are referred to as a “+Z direction” and a “−Z direction”, respectively.

The substrate processing part SP includes a holding/rotating mechanism 2, a scattering preventing mechanism 3, an upper surface protecting/heating mechanism 4, a processing mechanism 5, an atmosphere separating mechanism 6, an elevating mechanism 7, a centering mechanism 8, and a substrate observing mechanism 9. These mechanisms are provided on the base member 17. Specifically, with reference to the base member 17 having rigidity higher than that of the chamber 11, the holding/rotating mechanism 2, the scattering preventing mechanism 3, the upper surface protecting/heating mechanism 4, the processing mechanism 5, the atmosphere separating mechanism 6, the elevating mechanism 7, the centering mechanism 8, and the substrate observing mechanism 9 are arranged to one another with a positional relation determined in advance.

As shown in FIG. 2, the holding/rotating mechanism 2 includes a substrate holder 2A for holding the substrate W substantially in a horizontal posture with a surface of the substrate W facing up and a rotating mechanism 2B for synchronously rotating the substrate holder 2A holding the substrate W and part of the scattering preventing mechanism 3. For this reason, when the rotating mechanism 2B operates in response to a rotation command from the control unit 10, the substrate W and a rotating cup 31 of the scattering preventing mechanism 3 are rotated about an axis of rotation AX extending in parallel to the vertical direction Z.

The substrate holder 2A includes the spin chuck 21 which is a disk-like member smaller than the substrate W. The spin chuck 21 is so provided that an upper surface thereof is substantially horizontal and a center axis thereof coincides with the axis of rotation AX. Especially in the present embodiment, as shown in FIG. 3, a center of the substrate holder 2A (which corresponds to the center axis of the spin chuck 21) is offset in the (+X) direction relative to a center 11g of the chamber 11. Specifically, the substrate holder 2A is arranged so that the center axis (axis of rotation AX) of the spin chuck 21 may be positioned at a processing position deviated from the center 11g of the internal space 12 toward a side of the conveyance opening 11b1 by a distance Lof in a plan view of the chamber 11 viewed from above. Further, for clarifying the later-described arrangement relation of the components of the apparatus, in the present specification, a virtual line passing through the center (axis of rotation AX) of the substrate holder 2A which is offset and being orthogonal to the conveyance path TP and another virtual line in parallel to the conveyance path TP are referred to as a “first virtual horizontal line VL1” and a “second virtual horizontal line VL2”, respectively.

A cylindrical rotary shaft 22 is coupled to a lower surface of the spin chuck 21. The rotary shaft 22 extends in the vertical direction Z with an axis line thereof coinciding with the axis of rotation AX. Further, the rotating mechanism 2B is connected to the rotary shaft 22.

The rotating mechanism 2B has a motor 23 which generates a rotational driving force for rotating the substrate holder 2A and the rotating cup 31 of the scattering preventing mechanism 3 and a power transmitter 24 for transmitting the rotational driving force. The motor 23 has a rotation shaft 231 rotating with generation of the rotational driving force. The motor 23 is provided at a motor attachment portion 171 of the base member 17 in a posture with the rotation shaft 231 extending vertically downward. In more detail, as shown in FIG. 3, the motor attachment portion 171 is a portion which is cut out in the (+X) direction while facing the maintenance opening 11d1. A cutout width (size in the Y direction) of this motor attachment portion 171 is almost equal to the width of the motor 23 in the Y direction. For this reason, the motor 23 is movable in the X direction with a side surface thereof engaged with the motor attachment portion 171.

The motor 23 is fixed to the base member 17 at the motor attachment portion 171 while positioning the motor 23 in the X direction. At a tip part of the rotation shaft 231 protruding downward from the base member 17, attached is a first pulley 241. At a lower end part of the substrate holder 2A, attached is a second pulley 242. In more detail, the lower end part of the substrate holder 2A is inserted into the through hole provided in a spin chuck attachment portion 172 of the base member 17 and protrudes downward from the base member 17. This protruding portion is provided with the second pulley 242. Then, an endless belt 243 is put over between the first pulley 241 and the second pulley 242. Thus, in the present embodiment, the first pulley 241, the second pulley 242, and the endless belt 243 constitute the power transmitter 24.

A through hole (not shown) is provided at a central part of the spin chuck 21 and communicates with an internal space of the rotary shaft 22. A pump 26 is connected to the internal space via a pipe 25 having a valve (not shown) disposed therein. This pump 26 and the valve are electrically connected to the control unit 10 and operate in response to a command from the control unit 10. In this way, a negative pressure and a positive pressure are selectively applied to the spin chuck 21. If the pump 26 applies a negative pressure to the spin chuck 21, for example, with the substrate W placed substantially in a horizontal posture on the upper surface of the spin chuck 21, the spin chuck 21 sucks and holds the substrate W from below. On the other hand, if the pump 26 applies a positive pressure to the spin chuck 21, the substrate W can be taken out from the upper surface of the spin chuck 21. Further, if the suction of the pump 26 is stopped, the substrate W is horizontally movable on the upper surface of the spin chuck 21.

A nitrogen gas supplier 29 is connected to the spin chuck 21 via a pipe 28 provided in a central part of the rotary shaft 22. The nitrogen gas supplier 29 supplies a nitrogen gas at a normal temperature supplied from a utility of a factory, in which the substrate processing system 100 is installed, to the spin chuck 21 at a flow rate and a timing corresponding to a nitrogen gas supply command from the control unit 10, and causes the nitrogen gas to flow from the central part to a radially outer side on the side of a lower surface Wb of the substrate W. Note that although the nitrogen gas is used in the present embodiment, another inert gas may be used. This point also applies to a heated gas discharged from a central nozzle to be described later. Further, the “flow rate” means a moving amount of a fluid such as the nitrogen gas per unit time.

The rotating mechanism 2B includes a power transmitter 27 (FIG. 2) for not only rotating the spin chuck 21 integrally with the substrate W, but also rotating the rotating cup 31 in synchronization with the former rotation. The power transmitter 27 includes an annular member 27a (FIG. 5) made of a non-magnetic material or resin, spin chuck side magnets (not shown) built-in the annular member 27a, and cup side magnets (not shown) built-in a lower cup 32, which is one component of the rotating cup 31. The annular member 27a is attached to the rotary shaft 22 and rotatable about the axis of rotation AX together with the rotary shaft 22. More particularly, the rotary shaft 22 includes a flange part 22a protruding radially outward at a position right below the spin chuck 21 as shown in FIG. 5. The annular member 27a is arranged concentrically with respect to the flange part 22a, and coupled and fixed by an unillustrated bolt or the like.

A plurality of spin chuck side magnets are arranged radially and at equal angular intervals (10° in the present embodiment) with the axis of rotation AX as a center on an outer peripheral edge part of the annular member 27a. In the present embodiment, an N-pole and an S-pole are respectively arranged on an outer side and an inner side of one of the two spin chuck side magnets adjacent to each other, and an S-pole and an N-pole are respectively arranged on an outer side and an inner side of the other magnet.

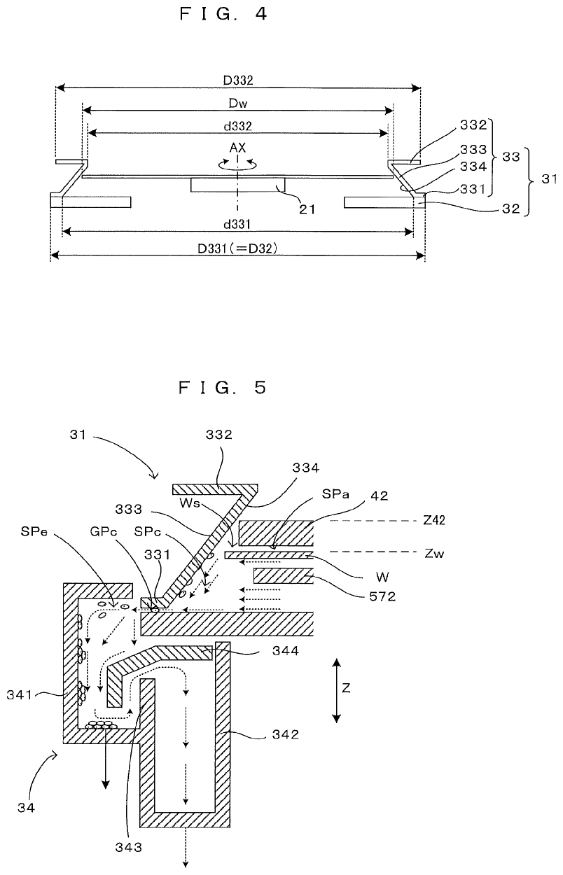

Similarly to these spin chuck side magnets, a plurality of cup side magnets are arranged radially and at equal angular intervals with the axis of rotation AX as a center. These cup side magnets are built in the lower cup 32. The lower cup 32 is a constituent component of the scattering preventing mechanism 3 to be described next and, as shown in FIGS. 4 and 5, has an annular shape. That is, the lower cup 32 has an inner peripheral surface capable of facing the outer peripheral surface of the annular member 27a. An inner diameter of this inner peripheral surface is larger than an outer diameter of the annular member 27a. The lower cup 32 is arranged concentrically with the rotary shaft 22 and the annular member 27a while this inner peripheral surface is separated from the outer peripheral surface of the annular member 27a by a predetermined distance (=(the inner diameter−the outer diameter)/2) and facing the outer peripheral surface of the annular member 27a. Engaging pins 35 and coupling magnets 36 are provided on the upper surface of the outer peripheral edge of the lower cup 32, the upper cup 33 is coupled to the lower cup 32 by these, and this coupled body functions as the rotating cup 31.

The lower cup 32 is supported rotatably about the axis of rotation AX on the upper surface of the base member 17 while being kept in the above arranged state by a bearing not shown in figures. The plurality of cup side magnets are arranged radially and at equal angular intervals with the axis of rotation AX as a center on an inner peripheral edge part of this lower cup 32. Further, two cup side magnets adjacent to each other are arranged similarly to the spin chuck side magnets. That is, an N-pole and an S-pole are respectively arranged on an outer side and an inner side of one magnet, and an S-pole and an N-pole are respectively arranged on an outer side and an inner side of the other magnet.

In the power transmitter 27 thus configured, if the annular member 27a is rotated together with the rotary shaft 22 by the motor 23, the lower cup 32 rotates in the same direction as the annular member 27a while maintaining an air gap GPa (gap between the annular member 27a and the lower cup 32) by the action of magnetic forces between the spin chuck side magnets and the cup side magnets. In this way, the rotating cup 31 rotates about the axis of rotation AX. That is, the rotating cup 31 rotates in the same direction as and in synchronization with the substrate W.

The scattering preventing mechanism 3 includes the rotating cup 31 rotatable about the axis of rotation AX while surrounding the outer periphery of the substrate W held on the spin chuck 21 and a fixed cup 34 fixedly provided to surround the rotating cup 31. The rotating cup 31 is provided rotatably about the axis of rotation AX while surrounding the outer periphery of the rotating substrate W by the upper cup 33 being coupled to the lower cup 32.

FIG. 4 is a diagram showing a dimensional relationship of the substrate held on the spin chuck and the rotating cup. FIG. 5 is a diagram partially showing a rotating cup and a fixed cup. The lower cup 32 has an annular shape. The lower cup 32 has an outer diameter larger than that of the substrate W and is arranged rotatably about the axis of rotation AX while radially protruding from the substrate W held on the spin chuck 21 in a plan view vertically from above. In this protruding region, i.e. an upper surface peripheral edge part 321 of the lower cup 32, the engaging pins 35 standing vertically upward and the flat plate-like lower magnets 36 are alternately mounted along a circumferential direction. A total of three engaging pins 35 are mounted, and a total of three lower magnets 36 are mounted. These engaging pins (not shown) and lower magnets (not shown) are arranged radially and at equal angular intervals with the axis of rotation AX as a center.

On the other hand, as shown in FIGS. 2 and 4, the upper cup 33 includes a lower annular part 331, an upper annular part 332 and an inclined part 333 coupling these. An outer diameter D331 of the lower annular part 331 is equal to an outer diameter D32 of the lower cup 32 and, as shown in FIG. 6, the lower annular part 331 is located vertically above the peripheral edge part 321 of the lower cup 32. Recesses 335 open downward are provided to be fittable to tip parts of the engaging pins 35 in regions vertically above the engaging pins 35 on the lower surface of the lower annular part 331. Further, upper magnets are mounted in regions vertically above the lower magnets. Thus, the upper cup 33 is engageable with and disengageable from the lower cup 32 with the recesses and the upper magnets respectively facing the engaging pins and the lower magnets.

The upper cup 33 is movable up and down along the vertical direction by the elevating mechanism 7. If the upper cup 33 is moved up by the elevating mechanism 7, a conveyance space for carrying in and out the substrate W is formed between the upper cup 33 and the lower cup 32 in the vertical direction. On the other hand, if the upper cup 33 is moved down by the elevating mechanism 7, the recesses 335 are fit to cover the tip parts of the engaging pins 35 and the upper cup 33 is positioned in a horizontal direction with respect to the lower cup 32. Further, the upper magnets 37 approach the lower magnets 36, and the positioned upper and lower cups 33, 32 are bonded to each other by attraction forces generated between both the magnets. In this way, as shown in the partial enlarged view of FIG. 3 and FIG. 5, the upper and lower cups 33, 32 are integrated in the vertical direction with a gap GPc extending in the horizontal direction formed. The rotating cup 31 is rotatable about the axis of rotation AX while forming the gap GPc.

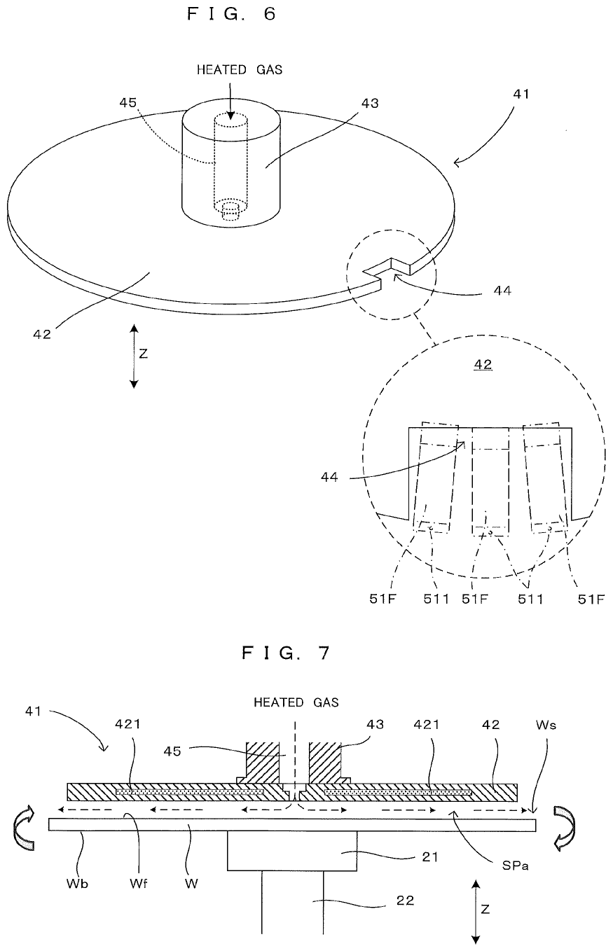

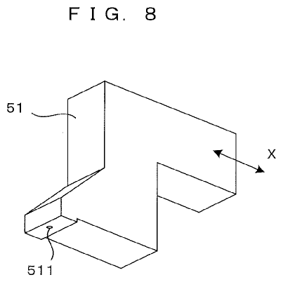

In the rotating cup 31, as shown in FIG. 4, an outer diameter D332 of the upper annular part 332 is slightly smaller than the outer diameter D331 of the lower annular part 331 as shown in FIG. 7. Further, if diameters d331, d332 of the inner peripheral surfaces of the lower and upper annular parts 331, 332 are compared, the lower annular part 331 is larger than the upper annular part 332 and the inner peripheral surface of the upper annular part 332 is located inside the inner peripheral surface of the lower annular part 331 in a plan view vertically from above. The inner peripheral surface of the upper annular part 332 and that of the lower annular part 331 are coupled by the inclined part 333 over the entire circumference of the upper cup 33. Thus, the inner peripheral surface of the inclined part 333, i.e. a surface surrounding the substrate W, serves as an inclined surface 334. That is, as shown in FIG. 8, the inclined part 333 can collect liquid droplets scattered from the substrate W by surrounding the outer periphery of the rotating substrate W, and a space surrounded by the upper and lower cups 33, 32 functions as a collection space SPc. Further, in the present embodiment, the vertical position of each part in the vertical direction Z is referred as follows. Specifically, as shown in FIG. 5, the position of the upper surface (front surface) of the substrate W held by the spin chuck 21 is referred to as a “vertical position Zw” and the position of the upper surface of a disk part 42 of the upper surface protecting/heating mechanism 4 described later in detail is referred to as a “vertical position Z42”.

Moreover, the inclined part 333 facing the collection space SPc is inclined upwardly of the peripheral edge part of the substrate W from the lower annular part 331 which is coupled to the lower cup 32, to thereby constitute a coupled part. For this reason, as shown in FIG. 5, the liquid droplets of the processing liquid scattered from the rotating substrate W are collected by the inclined surface 334 of the inclined part 333 at the vertical position Zw. Then, the liquid droplets can flow to a lower end part of the upper cup 33, i.e. the lower annular part 331, along the inclined surface 334, and can be discharged to the outside of the rotating cup 31 via the gap GPc.

The fixed cup 34 is provided to surround the rotating cup 31 and forms a discharge space SPe. The fixed cup 34 includes a liquid receiving part 341 and an exhaust part 342 provided inside the liquid receiving part 341. The liquid receiving part 341 has a cup structure open to face an opening (left opening of FIG. 5) of the gap GPc on a side opposite to the substrate. That is, an internal space of the liquid receiving part 341 functions as the discharge space SPe and communicates with the collection space SPc via the gap GPc. Therefore, the liquid droplets collected by the rotating cup 31 are guided into the discharge space SPe via the gap GPc together with gas components. Then, the liquid droplets are collected in a bottom part of the liquid receiving part 341 and discharged from the fixed cup 34.

On the other hand, the gas components are collected into the exhaust part 342. This exhaust part 342 is partitioned from the liquid receiving part 341 via a partition wall 343. Further, a gas guiding part 344 is arranged above the partition wall 343. The gas guiding part 344 extends from a position right above the partition wall 343 into the discharge space SPe and the exhaust part 342, thereby forming a flow passage for gas components having a labyrinth structure by covering the partition wall 343 from above. Accordingly, the gas components, out of a fluid flowing into the liquid receiving part 341, are collected in the exhaust part 342 by way of the flow passage. This exhaust part 342 is connected to an exhaust part 38. Thus, a pressure in the fixed cup 34 is adjusted by the operation of the exhaust part 38 in response to a command from the control unit 10, and the gas components in the exhaust part 342 are efficiently exhausted. Further, a pressure and a flow rate in the discharge space SPe are adjusted by a precise control of the exhaust part 38. For example, the pressure in the discharge space SPe is reduced to below that in the collection space SPc. As a result, the liquid droplets in the collection space SPc can be efficiently drawn into the discharge space SPe and movements of the liquid droplets from the collection space SPc can be promoted.

FIG. 6 is an external perspective view showing a configuration of an upper surface protecting/heating mechanism. FIG. 7 is a sectional view of the upper surface protecting/heating mechanism shown in FIG. 6. The upper surface protecting/heating mechanism 4 includes a shielding plate 41 arranged above the upper surface Wf of the substrate W held on the spin chuck 21. This shielding plate 41 includes a disk part 42 held in a horizontal posture. The disk part 42 has a built-in heater 421 drive-controlled by a heater driver 422. This disk part 42 has a diameter slightly shorter than that of the substrate W. The disk part 42 is so supported by a support member 43 that the lower surface of the disk part 42 covers a surface region excluding the peripheral edge part Ws, out of the upper surface Wf of the substrate W, from above. Note that reference sign 44 in FIG. 6 denotes a cut provided in a peripheral edge part of the disk part 42, and this cut is provided to prevent interference with processing liquid discharge nozzles included in the processing mechanism 5. The cut 44 is opened radially outward.

A lower end part of the support member 43 is mounted in a central part of the disk part 42. The cylindrical through hole is formed to vertically penetrate through the support member 43 and the disk part 42. Further, a center nozzle 45 is vertically inserted into this through hole. As shown in FIG. 2, the nitrogen gas supplier 47 is connected to this center nozzle 45 via a pipe 46. The nitrogen gas supplier 47 heats a nitrogen gas at a normal temperature supplied from utilities of the factory in which the substrate processing system 100 is installed and supplies the heated gas to the center nozzle 45 at a flow rate and a timing corresponding to a heated gas supply command from the control unit 10.

Herein, when the heater 421 is disposed in the internal space 12 of the chamber 11, there is a possibility that the heat radiated from the heater 421 may adversely affect the substrate processing part SP, in particular, the processing mechanism 5 and the substrate observing mechanism 9 described later. Then, in the present embodiment, the nitrogen gas supplier 47 having the heater 421 is disposed outside the chamber 11 as shown in FIG. 3. Further, in the present embodiment, a ribbon heater 48 is mounted in a part of the pipe 46. The ribbon heater 48 generates heat in response to a heating command from the control unit 10 to heat the nitrogen gas flowing in the pipe 46.

The nitrogen gas (hereinafter, referred to as a “heated gas”) heated in this way is fed under pressure toward the center nozzle 45 and discharged from the center nozzle 45. For example, as shown in FIG. 7, by supplying the heated gas with the disk part 42 positioned at a processing position near the substrate W held on the spin chuck 21, the heated gas flows toward a peripheral edge part from a central part of a space SPa sandwiched between the upper surface Wf of the substrate W and the disk part 42 including the built-in heater. In this way, an atmosphere around the substrate W can be suppressed from reaching the upper surface Wf of the substrate W. As a result, the liquid droplets included in the atmosphere can be effectively prevented from getting in the space SPa sandwiched between the substrate W and the disk part 42. Further, the upper surface Wf is entirely heated by heating of the heater 421 and the heated gas, whereby an in-plane temperature of the substrate W can be made uniform. In this way, the warping of the substrate W can be suppressed and a liquid landing position of the processing liquid can be stabilized.

As shown in FIG. 2, an upper end part of the support member 43 is fixed to a beam member 49 extending along the first virtual horizontal line VL1. This beam member 49 is connected to the elevating mechanism 7 installed on the upper surface of the base member 17 and moved up and down by the elevating mechanism 7 in response to a command from the control unit 10. For example, in FIG. 2, the beam member 49 is positioned below, whereby the disk part 42 coupled to the beam member 49 is located at the processing position via the support member 43. On the other hand, if the elevating mechanism 7 moves up the beam member 49 in response to a move-up command from the control unit 10, the beam member 49, the support member 43 and the disk part 42 integrally move upward and the upper cup 33 is also linked, separated from the lower cup 32 and moves up. In this way, the upper cup 33 and the disk part 42 are spaced wider apart from the spin chuck 21 and the substrate W can be carried to and from the spin chuck 21.

The processing mechanism 5 includes processing liquid discharge nozzles 51F (see FIG. 3) arranged on the upper surface side of the substrate W, processing liquid discharge nozzles 51B (see FIG. 2) arranged on the lower surface side of the substrate W and processing liquid suppliers 52 for supplying the processing liquid to the processing liquid discharge nozzles 51F, 51B. The processing liquid discharge nozzles 51F on the upper surface side and the processing liquid discharge nozzles 51B on the lower surface side are respectively referred to as “upper-surface processing nozzles 51F” and “lower-surface processing nozzles 51B” to be distinguished. Further, two processing liquid suppliers 52 shown in FIG. 2 are identical.

FIG. 8 is a perspective view showing a processing liquid discharge nozzle on an upper surface side equipped in the processing mechanism and a view of the nozzle viewed from a diagonally downward direction. In the present embodiment, three upper-surface processing nozzles 51F are provided as the processing liquid discharge nozzles on the upper surface side, which discharges the processing liquid toward the peripheral edge part Ws of the upper surface Wf of the substrate W from above the substrate W held by the spin chuck 21, and the processing liquid supplier 52 is connected thereto. Further, the processing liquid supplier 52 is configured to be capable of supplying SC1, DHF and functional water (CO₂ water or the like) as the processing liquids, and the SC1, DHF and CO₂ water can be independently discharged from the three upper-surface processing nozzles 51F, respectively.

As shown in FIG. 8, each of the upper-surface processing nozzles 51F is provided with a discharge port 511 for discharging the processing liquid on a lower surface of a tip thereof. Then, as shown in an enlarged view in FIG. 3, with each of the discharge ports facing the peripheral edge part Ws of the upper surface Wf of the substrate W, respective lower parts of a plurality of (three in the present embodiment) upper-surface processing nozzles 51F are arranged in the cut 44 of the disk part 42 as shown in a partial enlarged plan view in FIG. 6 and respective upper parts of the upper-surface processing nozzles 51F are mounted movably to a nozzle holder 53 in a radial direction D1. This nozzle holder 53 is connected to a nozzle mover 54.

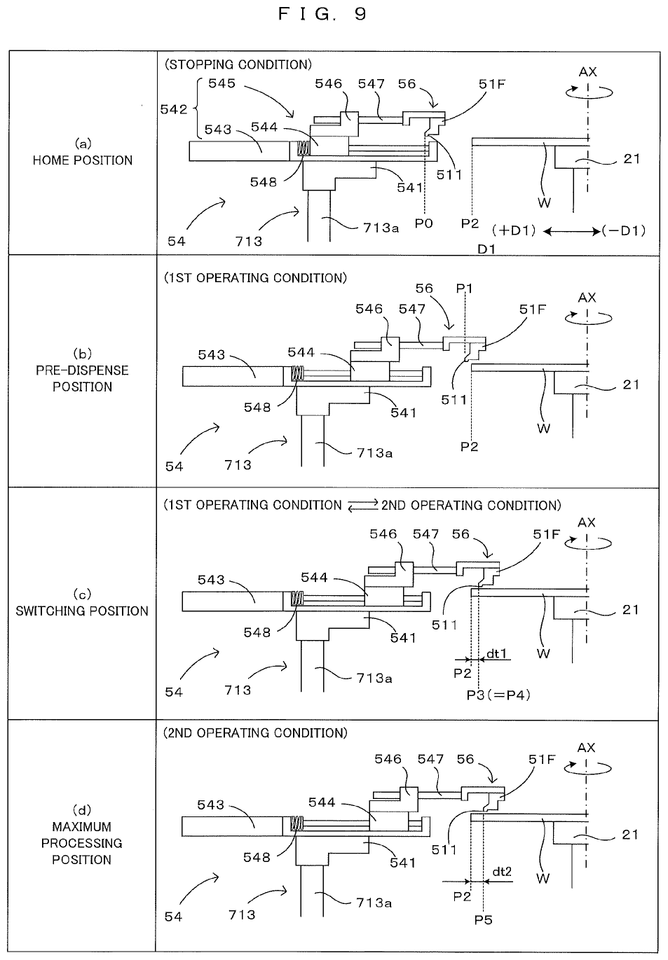

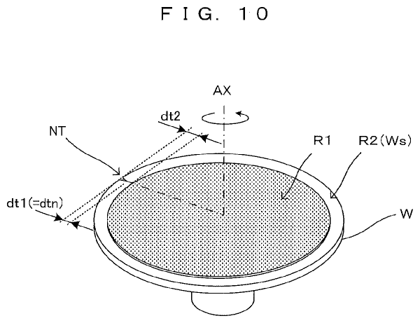

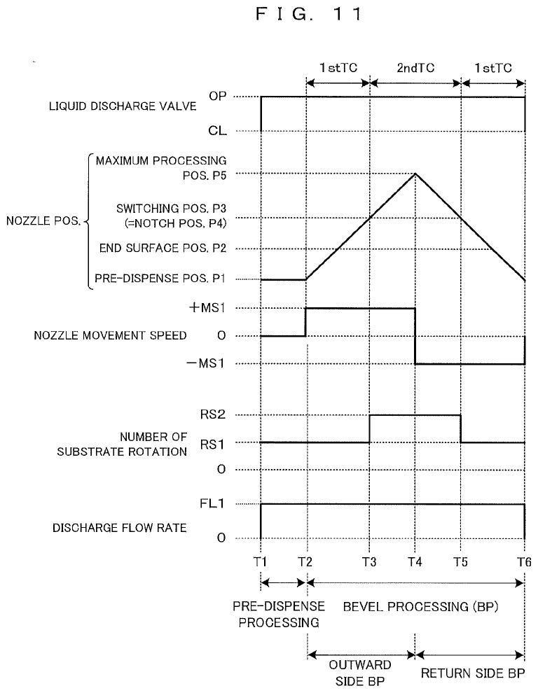

FIG. 9 is a diagram schematically showing the configuration and operation of the nozzle mover. Further, FIG. 10 is a diagram schematically showing an exemplary relation of a region to be subjected to a bevel processing, a notch, and a substrate end surface. A section (a) of FIG. 9 is a schematic diagram showing a home position, a section (b) of FIG. 9 is a schematic diagram showing a pre-dispense position, a section (c) of FIG. 9 is a schematic diagram showing a switching position where an operating condition is switched, and a section (d) of FIG. 9 is a schematic diagram showing a maximum processing position. Reference sign P0 in FIG. 9 denotes the home position of the upper-surface processing nozzles 51F, and reference signs P1 to P5 denote the pre-dispense position, the end surface position of the substrate W, the switching position, the notch position, and the maximum processing position, respectively, in the radial direction D1. Furthermore, in FIG. 10, a region with dots represents a non-bevel processing region R1 which is left, not having been subjected to the bevel processing, and a region on the front surface of the substrate W other than the non-bevel processing region R1 represents a bevel processing region R2 to be subjected to the bevel processing.

As shown in FIG. 9, the nozzle mover 54 is attached to an upper end part of a lifter 713a of an elevator 713 described later while holding the nozzle head 56 (=the upper surface processing nozzle 51F+the nozzle holder 53). For this reason, in response to an up-and-down command from the control unit 10, the lifter 713a expands and contracts in the vertical direction and accordingly the nozzle mover 54 and the nozzle head 56 move in the vertical direction Z.

Further, in the nozzle mover 54, a base member 541 is fixed to the upper end part of the lifter 713a. To this base member 541, attached is a linear actuator 542. The linear actuator 542 has a motor (hereinafter, referred to as a “nozzle drive motor”) 543 serving as a drive source of nozzle movement in the radial direction X and a motion conversion mechanism 545 for converting a rotational motion of a rotating body such as a ball screw or the like coupled to an axis of rotation of the nozzle drive motor 543 into a linear motion to thereby cause a slider 544 to reciprocally move in the radial direction D1. Further, in the motion conversion mechanism 545, in order to stabilize the movement of the slider 544 in the radial direction D1, a guide such as an LM guide (registered trademark) or the like is used.

To the slider 544 driven reciprocally in the radial direction X, a head support member 547 is coupled with a coupling member 546 interposed therebetween. This head support member 547 has a bar shape extending in the radial direction X. An end part of the head support member 547 in the (+D1) direction is fixed to the slider 544. On the other hand, an end part of the head support member 547 in the (−D1) direction is horizontally extended toward the spin chuck 21, and the nozzle head 56 is attached to a tip part thereof. For this reason, when the nozzle drive motor 543 is rotated in response to a processing liquid supply command from the control unit 10, the slider 544, the head support member 547, and the nozzle head 56 are integrally moved in the (+D1) direction or the (−D1) direction in accordance with a rotation direction thereof by a distance corresponding to the amount of rotation. As a result, the upper-surface processing nozzle 51F attached to the nozzle head 56 is positioned in the radial direction D1.

Thus, in response to the information on the nozzle reciprocating movement in the processing liquid supply command from the control unit 10, the nozzle mover 54 collectively drives the three upper-surface processing nozzles 51F toward the direction D1. The upper-surface processing nozzles 51F are thereby reciprocatingly moved while the pre-dispense processing and the bevel processing are performed. On the other hand, while the processing liquid supply command is not given on any one of the three types of processing liquids, the upper-surface processing nozzles 51F are retracted, being sufficiently away from the end surface of the substrate W. More specifically, as shown in the section (a) of FIG. 9, the upper-surface processing nozzles 51F are positioned at the home position P0 which is set in advance. At that time, a spring member 548 provided in the motion conversion mechanism 545 is compressed by the slider 544, to thereby give an urging force to the slider 544 in the (−D1) direction. It is thereby possible to control backlash included in the motion conversion mechanism 545. Specifically, since the motion conversion mechanism 545 has mechanical components such as a guide or the like, it is practically difficult to make the backlash along the radial direction D1 zero, and the positioning accuracy of the upper-surface processing nozzles 51F in the radial direction D1 is reduced if not sufficient consideration is made thereon. Then, in the present embodiment, by providing the spring member 548, when the upper-surface processing nozzles 51F are immobilized at the home position P0, the backlash is always one-sided toward the (−D1) direction.

When the processing liquid supply command is given on one processing liquid (hereinafter, referred to as a “selected processing liquid”) among the three types of processing liquids, the upper-surface processing nozzles 51F are collectively moved from the home position P0 toward the (−D1) direction. After that, the upper-surface processing nozzles 51F are moved on an outward through the end surface position P2 and the switching position P3 to the maximum processing position P5. Herein, the switching position P3 refers to a position away from an end surface of the substrate by a distance dt1 and the maximum processing position P5 refers to a position away from the end surface of the substrate by a width dt2 of the bevel processing region R2 (see FIG. 10).

During the outward movement, the movement of the upper-surface processing nozzles 51F is paused at the pre-dispense position P1. As shown in THE SECTION (B) OF FIG. 9, the pre-dispense position P1 is a position adjacent to the end surface position P2 on the (+D1) side in the radial direction D1. The discharge ports 511 of the upper-surface processing nozzles 51F positioned at the pre-dispense position are directed toward the inclined surface 334 of the upper cup 33. Then, in response to the processing liquid supply command, the pre-dispense processing is performed. After the pre-dispense processing is finished, the pause is cancelled and the outward movement is resumed. The upper-surface processing nozzles 51F are thereby moved through the switching position P3 (see the section (c) of FIG. 9) to the maximum processing position P5 (see the section (d) of FIG. 9). In the present embodiment, this switching position P3 is made coincident with the notch position P4. Specifically, as shown in FIG. 10, a notch NT provided at the peripheral edge part Ws of the substrate W has a substantially V-shape or a substantially U-shape in a plan view viewed from above. In other words, in the notch NT, a cut part has a more tapered shape as it goes from the end surface of the substrate W toward a central part thereof, and there is no cut part inside a position where it goes from the end surface of the substrate W toward the central part thereof by a distance dtn. Specifically, the position corresponds to the deepest position of the notch NT, and the distance dtn from the end surface of the substrate W to the deepest position corresponds to an exemplary “distance to the deepest position of the cut” of the present invention. Particularly, in the first embodiment, considering that the distance dtn is shorter than the width dt2 on which the bevel processing should be performed, the switching position P3 is made coincident with the notch position P4. Further, a case where the distance dtn is not shorter than the width dt2 on which the bevel processing should be performed will be described later.

When the outward movement is completed, a return movement is immediately performed. Specifically, the upper-surface processing nozzles 51F are moved on a route reverse to that of the outward movement. In the return movement, however, there is no pause at the pre-dispense position P1 but the upper-surface processing nozzles 51F are continuously moved from the maximum processing position P5 to the home position P0.

Thus, while the upper-surface processing nozzles 51F are reciprocatingly moved, the constituents of the apparatus operate in accordance with the information on the pre-dispense processing and the bevel processing included in the processing liquid supply command, and the pre-dispense processing and the bevel processing are performed. More specifically, the following control items are controlled in accordance with the processing liquid supply command:
opening/closing of a liquid discharge valve (not shown) provided in the processing liquid supplier 52;
position control of the upper-surface processing nozzles 51F in the radial direction D1;
nozzle movement speed of the upper-surface processing nozzles 51F;
the number of rotation of the substrate W; and
the discharge amount of selected processing liquid from the upper-surface processing nozzles 51F per unit time. Hereinafter, the pre-dispense processing and the bevel processing performed in the first embodiment will be described.

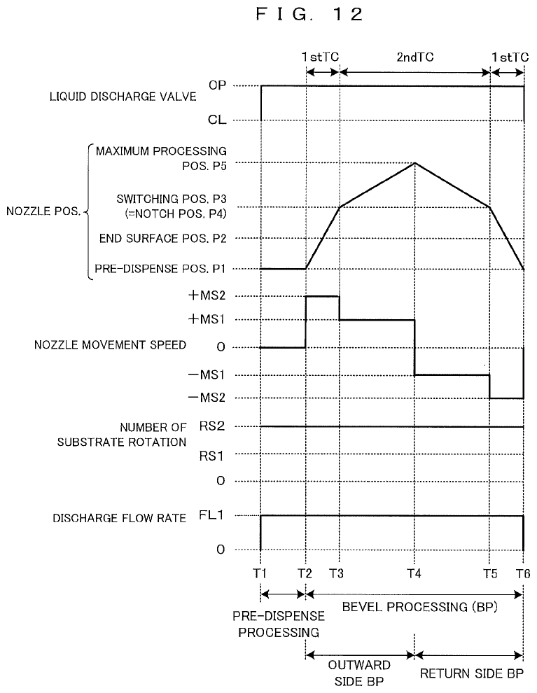

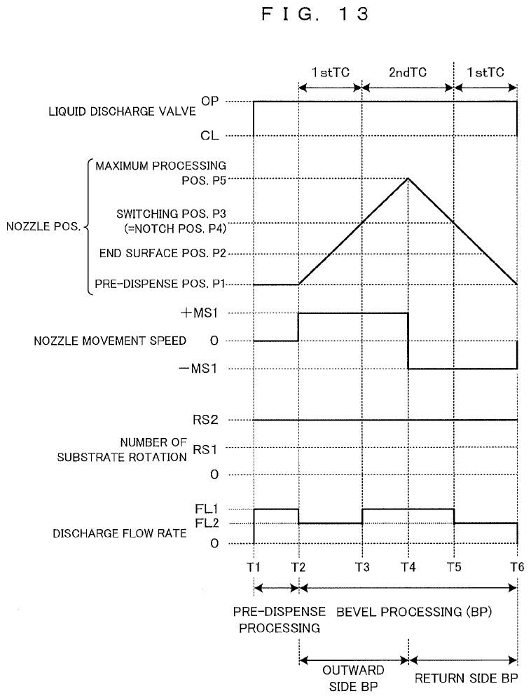

FIG. 11 is a timing chart of the pre-dispense processing and the bevel processing performed in the first embodiment of the substrate processing apparatus according to the present invention. Reference signs 1stTC and 2ndTC in this figure and FIGS. 12 to 17 described later denote a first operating condition and a second operating condition, respectively. In the first embodiment, the processing liquid supply command is waited to be given from the control unit 10 in a state where the upper-surface processing nozzles 51F are positioned at the home position P0, as shown in the section (a) of FIG. 9. At that time, a stopping condition is satisfied. This stopping condition indicates that the liquid discharge valve is closed and as a result, the discharge flow rate is zero. Further, the nozzle movement speed is zero and the movement of the upper-surface processing nozzles 51F is stopped. Then, when the processing liquid supply command is received, the constituents of the apparatus operate in a sequence shown in FIG. 11.

The upper-surface processing nozzles 51F are moved from the home position P0 in the radial direction (−D1) and positioned at the pre-dispense position P1 (timing T1). Then, the nozzle movement speed becomes zero, and the upper-surface processing nozzles 51F are paused until next timing T2. During this pause (timings T1 to T2), the pre-dispense processing is performed. Specifically, the liquid discharge valve starts to be opened, and the selected processing liquid starts to be discharged at a certain discharge flow rate FL1. Note that discharge of the selected processing liquid continues to be performed until the upper-surface processing nozzles 51F returns to the pre-dispense position P1. Furthermore, the number of rotation of the substrate W is arbitrary during the pre-dispense processing, but in the first embodiment, the number of rotation is set to the number of substrate rotation RS1 which is relatively low, correspondingly to the next bevel processing. In this point, the same applies to the fourth embodiment, the fifth embodiment, and the seventh embodiment described later.

Subsequently to the pre-dispense processing, the bevel processing in parallel with the outward movement (hereinafter, referred to as an “outward side bevel processing”) and the bevel processing in parallel with the return movement (hereinafter, referred to as a “return side bevel processing”) are continuously performed. Particularly, in the first embodiment, while the control items other than the number of substrate rotation are maintained constant, the number of substrate rotation is switched at some midpoint of the outward side bevel processing and the return side bevel processing. It is thereby possible to prevent or suppress the liquid splash caused by the notch NT (FIG. 10) which is an exemplary cut of the present invention.

In more detail, in the outward side bevel processing (timings T2 to T4), the nozzle movement speed is increased from zero to a speed (+MS1) by a predetermined acceleration. Then, the upper-surface processing nozzles 51F are moved constantly at the speed (+MS1) in the (−D1) direction. Further, the selected processing liquid is also continuously discharged at a constant discharge flow rate FL1. For this reason, the upper-surface processing nozzles 51F pass above the end surface position P2 of the substrate W and are further moved through above the notch position P4 to the maximum processing position P5 while the selected processing liquid is discharged from the upper-surface processing nozzle 51F corresponding to the selected processing liquid. Herein, in order to cause or suppress the liquid splash at the notch NT, the number of substrate rotation in the first half of the outward side bevel processing (timings T2 to T3) is reduced to the number of rotation RS1 which is relatively low. On the other hand, the number of substrate rotation is increased from the number of rotation RS1 to the number of rotation RS2 at timing T3, and the number of substrate rotation is increased to the number of rotation RS2 (>RS1) suitable for the bevel processing during the second half of the outward side bevel processing (timings T3 to T4). For this reason, the number of passings of the notch NT over a position immediately below the upper-surface processing nozzles 51F per unit time is small and the amount of selected processing liquid arriving at the notch NT, i.e., the cut-arrival amount, is also low. As a result, it is possible to reduce the amount of liquid splash occurring in the outward side bevel processing.

Thus, when the outward side bevel processing is completed, the return side bevel processing is immediately performed. In the return side bevel processing (timings T4 to T6), the nozzle movement speed is reduced from the speed (+MS1) to zero by a predetermined acceleration/deceleration, and further increased from zero to the speed (−MS1). Herein, the plus sign and the minus sign of the nozzle movement speed indicate the moving directions of the upper-surface processing nozzles 51F, whether an outward direction (−D1) or a return direction (+D1), respectively, and “MS1” denotes an absolute value of the movement speed. The same applies to the nozzle movement speeds (+MS2) and (−MS2) described later.

In the return side bevel processing, the upper-surface processing nozzles 51F are moved constantly at the above-described nozzle movement speed (−MS2). Further, the selected processing liquid is also continuously discharged at the constant discharge flow rate FL1. For this reason, subsequently to the outward side bevel processing, the upper-surface processing nozzles 51F are moved through above the switching position P3 (the notch position P4) to the pre-dispense position P1 while the selected processing liquid is discharged from the upper-surface processing nozzle 51F corresponding to the selected processing liquid. Also herein, in order to cause or suppress the liquid splash at the notch NT, the number of substrate rotation is switched at the point in time when the upper-surface processing nozzles 51F reach above the switching position P3 (the notch position P4). Specifically, in the first half of the return side bevel processing (timings T4 to T5), the bevel processing is performed while the number of substrate rotation is maintained at the number of rotation RS2 suitable for the bevel processing, and on the other hand, in the second half (timings T5 to T6), the number of substrate rotation is reduced to the number of rotation RS1 which is relatively low. For this reason, the number of passings of the notch NT over the position immediately below the upper-surface processing nozzles 51F per unit time is small and the amount of selected processing liquid arriving at the notch NT, i.e., the cut-arrival amount, is also low. As a result, it is possible to reduce the amount of liquid splash occurring also in the return side bevel processing.

Thus, in the first embodiment, set are a first operating condition which is a condition to reduce the number of substrate rotation to the number of rotation RS1 which is relatively low and a second operating condition which is a condition to set the number of substrate rotation to the number of rotation RS2 suitable for the bevel processing. Then, in each of the outward side bevel processing and the return side bevel processing, the first operating condition and the second operating condition are switched in accordance with the notch position P4. As a result, it is possible to effectively suppress occurrence of particles by preventing or suppressing occurrence of the liquid splash caused by the notch NT.

In this first embodiment, the rotating mechanism 2B corresponds to an exemplary “rotating part” of the present invention. Further, the width dt2 of the bevel processing region R2 corresponds to an exemplary “bevel processing distance” of the present invention. The outward side bevel processing and the return side bevel processing correspond to an exemplary “operation (b)” and an exemplary “operation (c)” of the present invention, respectively, and an operation of rotating the substrate W in these processings (steps) corresponds to an exemplary “rotation step” of the present invention. Furthermore, the control unit 10 corresponds to an exemplary “controller” of the present invention.

Further, the nozzle movement during timings T1 to T2 corresponds to an exemplary “first outward movement” of the present invention. The nozzle movement during timings T2 to T3 corresponds to an exemplary “second outward movement” of the present invention. The nozzle movement during timings T4 to T5 corresponds to an exemplary “second return movement” of the present invention. The nozzle movement during timings T5 to T6 corresponds to an exemplary “first return movement” of the present invention.

Further, the switching position P3 corresponds to an exemplary “intermediate position” of the present invention and is made coincident with the notch position P4. The position of the switching position P3 is, however, not limited to this, but the switching position P3 may be set, for example, between the notch position P4 and the maximum processing position P5 in the radial direction D1. Furthermore, the switching position P3 may be set between the end surface position P2 and the notch position P4 in the radial direction D1. In these points, the same applies to the second embodiment to the seventh embodiment described later.

The control items affecting the cut-arrival amount include not only the above-described number of substrate rotation but also the nozzle movement speed, the discharge flow rate of the selected processing liquid, and the like. In the above-described first embodiment, while the nozzle movement speed and the discharge flow rate are fixed, the first operating condition and the second operating condition are switched by changing only the number of substrate rotation. As a matter of course, in order to change the cut-arrival amount, it may be configured to change part or all of the above-described three control items. Specifically, only the nozzle movement speed may be changed (the second embodiment), only the discharge flow rate may be changed (the third embodiment), the number of substrate rotation and the nozzle movement speed may be changed (the fourth embodiment), the number of substrate rotation and the discharge flow rate may be changed (the fifth embodiment), the nozzle movement speed and the discharge flow rate may be changed (the sixth embodiment), or the nozzle movement speed and the discharge flow rate may be changed (the seventh embodiment). Hereinafter, the second embodiment to the seventh embodiment will be described.

### The Second Embodiment

FIG. 12 is a timing chart of the pre-dispense processing and the bevel processing performed in the second embodiment of the substrate processing apparatus according to the present invention. Hereinafter, the pre-dispense processing and the bevel processing in the second embodiment will be described in comparison with those in the first embodiment, centering on the difference from the first embodiment.

Like in the first embodiment, the pre-dispense processing is performed between the timing T1 and the timing T2 while the nozzle movement is paused. In the second embodiment, however, in order to maintain the number of rotation of the substrate W at the constant number of substrate rotation RS2 in the next bevel processing, the number of rotation of the substrate W during the pre-dispense processing is set to the number of substrate rotation RS2 which is higher than that in the first embodiment. In this point, the same applies to the third embodiment and the sixth embodiment described later.

In the outward side bevel processing (timings T2 to T4) subsequent to the pre-dispense processing, as described above, the number of rotation of the substrate W is maintained at the number of substrate rotation RS2 and the selected processing liquid is also continuously discharged at the constant discharge flow rate FL1. In contrast to this, the movement speed of the upper-surface processing nozzles 51F, i.e., the nozzle movement speed, is changed as follows. From the timing T2, the nozzle movement speed is increased from zero to a nozzle movement speed (+MS2) which is higher than that in the first embodiment by a predetermined acceleration. Then, in the first half of the outward side bevel processing (timings T2 to T3), the upper-surface processing nozzles 51F are moved constantly at the above-described nozzle movement speed (+MS2). At the timing T3, the nozzle movement speed is reduced to the speed (+MS1) suitable for the bevel processing by a predetermined deceleration. Specifically, the bevel processing is performed under the first operating condition (=the nozzle movement speed (+MS2): the number of substrate rotation RS2: the discharge flow rate FL1) until the upper-surface processing nozzles 51F reach the switching position P3, and at the switching position P3, the operating condition is switched to the second operating condition (=the nozzle movement speed (+MS1): the number of substrate rotation RS2: the discharge flow rate FL1). Thus, during a period while the upper-surface processing nozzles 51F are moved through above the end surface of the substrate W and above the notch NT to the switching position P3, i.e., in the first half of the outward side bevel processing (timings T2 to T3), the upper-surface processing nozzles 51F are moved at a relatively high speed. For this reason, a cumulative time while the upper-surface processing nozzles 51F are positioned above the notch NT becomes less, and the amount of selected processing liquid arriving at the notch NT, i.e., the cut-arrival amount, also becomes lower. As a result, it is possible to prevent occurrence of the liquid splash or reduce the amount of liquid splash in the outward side bevel processing.

Thus, when the outward side bevel processing is completed, the return side bevel processing is immediately performed. In the return side bevel processing (timings T4 to T6), the nozzle movement speed is reduced from the speed (+MS1) to zero by a predetermined acceleration/deceleration, and further increased from zero to the speed (−MS1). Then, the upper-surface processing nozzles 51F are moved constantly at the nozzle movement speed (−MS1). On the other hand, the substrate W is rotated at the constant number of substrate rotation RS2 and the selected processing liquid is also continuously discharged at the constant discharge flow rate FL1. For this reason, subsequently to the outward side bevel processing, the upper-surface processing nozzles 51F are moved to the switching position P3 (the notch position P4) while the selected processing liquid is discharged from the upper-surface processing nozzle 51F corresponding to the selected processing liquid. Then, at this timing T5, the nozzle movement speed is increased from the speed (−MS1) to the speed (−MS2) by a predetermined acceleration. Specifically, the bevel processing is performed under the second operating condition (=the nozzle movement speed (−MS1): the number of substrate rotation RS2: the discharge flow rate FL1) until the upper-surface processing nozzles 51F reach the switching position P3. Then, at the point in time when the upper-surface processing nozzles 51F reach the switching position P3, the operating condition is switched to the first operating condition (=the nozzle movement speed (−MS2): the number of substrate rotation RS2: the discharge flow rate FL1). After that, the upper-surface processing nozzles 51F are moved through above the notch NT and above the end surface of the substrate and return to the pre-dispense position P1 (timing T6) under the first operating condition. For this reason, the amount of selected processing liquid arriving at the notch NT, i.e., the cut-arrival amount, becomes lower. As a result, it is possible to prevent occurrence of the liquid splash or reduce the amount of liquid splash also in the return side bevel processing.

Thus, also in the second embodiment, in each of the outward side bevel processing and the return side bevel processing, the first operating condition and the second operating condition are switched in accordance with the switching position P3 (=the notch position P4). As a result, like in the first embodiment, it is possible to effectively suppress occurrence of particles by preventing or suppressing occurrence of the liquid splash caused by the notch NT.

### The Third Embodiment

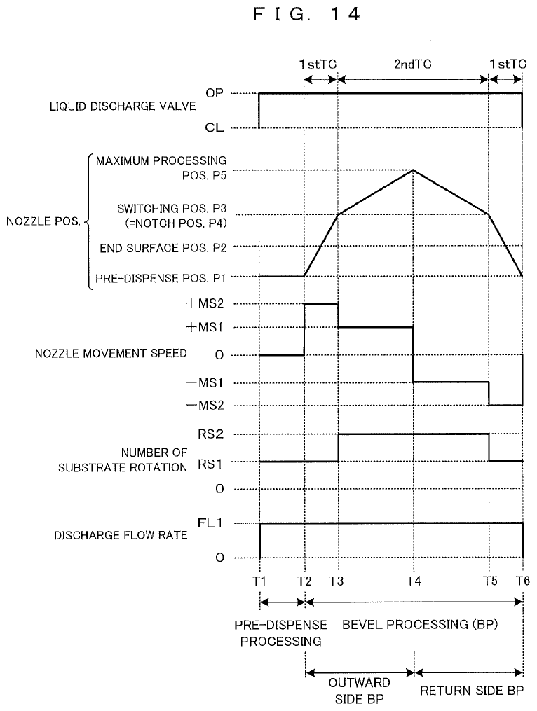

FIG. 13 is a timing chart of the pre-dispense processing and the bevel processing performed in the third embodiment of the substrate processing apparatus according to the present invention. Hereinafter, the pre-dispense processing and the bevel processing in the third embodiment will be described in comparison with those in the first embodiment, centering on the difference from the first embodiment.

Like in the first embodiment, the pre-dispense processing is performed between the timing T1 and the timing T2 while the nozzle movement is paused. Further, in the outward side bevel processing (timings T2 to T4) subsequent to the pre-dispense processing, as described above, the number of rotation of the substrate W is maintained at the number of substrate rotation RS2 and the nozzle movement speed is set to the constant speed (+MS1). In contrast to this, the discharge flow rate of the selected processing liquid is reduced from the discharge flow rate FL1 to a discharge flow rate FL2 at the timing T2. Then, in the first half of the outward side bevel processing (timings T2 to T3), the above-described discharge flow rate FL2 (<FL1) is maintained. At the timing T3, the discharge flow rate of the selected processing liquid is returned to the discharge flow rate FL1. Specifically, the bevel processing is performed under the first operating condition (=the nozzle movement speed (+MS1): the number of substrate rotation RS2: the discharge flow rate FL2) until the upper-surface processing nozzles 51F reach the switching position P3, and at the switching position P3, the operating condition is switched to the second operating condition (=the nozzle movement speed (+MS1): the number of substrate rotation RS2: the discharge flow rate FL1). Thus, during a period while the upper-surface processing nozzles 51F are moved through above the end surface of the substrate W and above the notch NT to the switching position P3, i.e., in the first half of the outward side bevel processing (timings T2 to T3), the discharge flow rate of the selected processing liquid discharged from the upper-surface processing nozzle 51F is suppressed to be relatively low. For this reason, the amount of selected processing liquid arriving at the notch NT, i.e., the cut-arrival amount, also becomes lower. As a result, it is possible to prevent occurrence of the liquid splash or reduce the amount of liquid splash in the outward side bevel processing.

Thus, when the outward side bevel processing is completed, the return side bevel processing is immediately performed. In the return side bevel processing (timings T4 to T6), the nozzle movement speed is reduced from the speed (+MS1) to zero by a predetermined acceleration/deceleration, and further increased from zero to the speed (−MS1). Then, the upper-surface processing nozzles 51F are moved constantly at the nozzle movement speed (−MS1) and the number of substrate rotation of the substrate W is maintained at a constant value RS2. In contrast to this, the discharge flow rate of the selected processing liquid is reduced from the discharge flow rate FL1 to a discharge flow rate FL2 at the timing T5. Specifically, in the return side bevel processing subsequent to the outward side bevel processing, the bevel processing is performed under the second operating condition (=the nozzle movement speed (−MS1): the number of substrate rotation RS2: the discharge flow rate FL1) until the upper-surface processing nozzles 51F reach the switching position P3. Then, at the point in time when the upper-surface processing nozzles 51F reach the switching position P3, the operating condition is switched to the first operating condition (=the nozzle movement speed (−MS1): the number of substrate rotation RS2: the discharge flow rate FL2). After that, the upper-surface processing nozzles 51F are moved through above the notch NT and above the end surface of the substrate and return to the pre-dispense position P1 (timing T6) under the first operating condition. For this reason, the amount of selected processing liquid arriving at the notch NT, i.e., the cut-arrival amount, becomes lower. As a result, it is possible to prevent occurrence of the liquid splash or reduce the amount of liquid splash also in the return side bevel processing.

Thus, in the third embodiment, in each of the outward side bevel processing and the return side bevel processing, the first operating condition and the second operating condition are switched in accordance with the switching position P3 (=the notch position P4). As a result, like in the first embodiment and the second embodiment, it is possible to effectively suppress occurrence of particles by preventing or suppressing occurrence of the liquid splash caused by the notch NT.

### The Fourth Embodiment

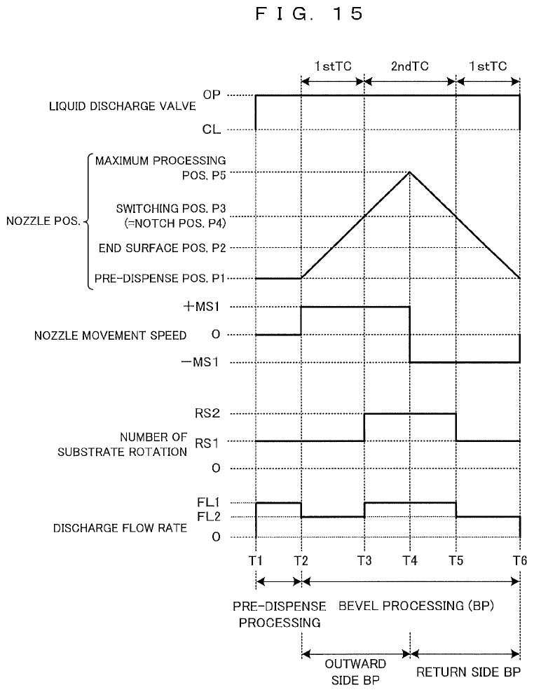

FIG. 14 is a timing chart of the pre-dispense processing and the bevel processing performed in the fourth embodiment of the substrate processing apparatus according to the present invention. In this fourth embodiment, the change in the number of substrate rotation made in the first embodiment and the change in the nozzle movement speed made in the second embodiment are combined. Specifically, in the outward side bevel processing and the return side bevel processing, the following switching of the operating conditions is performed.

In the outward side bevel processing, the bevel processing is performed under the first operating condition (=the nozzle movement speed (+MS2): the number of substrate rotation RS1: the discharge flow rate FL1) until the upper-surface processing nozzles 51F reach the switching position P3, and at the switching position P3, the operating condition is switched to the second operating condition (=the nozzle movement speed (+MS1): the number of substrate rotation RS2: the discharge flow rate FL1). Thus, during a period while the upper-surface processing nozzles 51F are moved through above the end surface of the substrate W and above the notch NT to the switching position P3, i.e., in the first half of the outward side bevel processing (timings T2 to T3), the cut-arrival amount is suppressed to be low, and as a result, it is possible to reduce the amount of liquid splash occurring in the outward side bevel processing.

Further, in the return side bevel processing, the bevel processing is performed under the second operating condition (=the nozzle movement speed (−MS1): the number of substrate rotation RS2: the discharge flow rate FL1) until the upper-surface processing nozzles 51F reach the switching position P3, and from the switching position P3, the operating condition is switched to the first operating condition (=the nozzle movement speed (−MS2): the number of substrate rotation RS1: the discharge flow rate FL1). Then, during a period while the upper-surface processing nozzles 51F are moved through above the notch NT and above the end surface of the substrate W to the pre-dispense position P1, i.e., in the second half of the return side bevel processing (timings T5 to T6), the cut-arrival amount is suppressed to be low, and as a result, it is possible to reduce the amount of liquid splash occurring in the return side bevel processing.

Thus, also in the fourth embodiment, in each of the outward side bevel processing and the return side bevel processing, the first operating condition and the second operating condition are switched in accordance with the switching position P3 (=the notch position P4). As a result, like in the first embodiment to the third embodiment, it is possible to effectively suppress occurrence of particles by preventing or suppressing occurrence of the liquid splash caused by the notch NT.

### The Fifth Embodiment

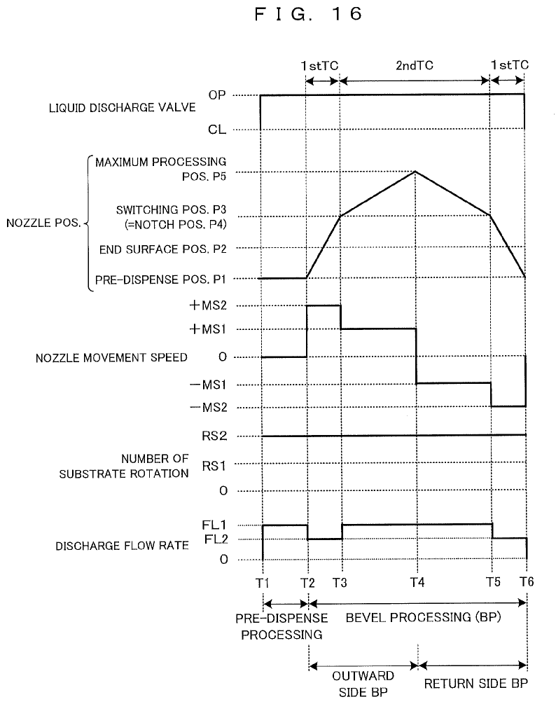

FIG. 15 is a timing chart of the pre-dispense processing and the bevel processing performed in the fifth embodiment of the substrate processing apparatus according to the present invention. In this fifth embodiment, the change in the number of substrate rotation made in the first embodiment and the change in the discharge flow rate made in the third embodiment are combined. Specifically, in the outward side bevel processing and the return side bevel processing, the following switching of the operating conditions is performed.

In the outward side bevel processing, the bevel processing is performed under the first operating condition (=the nozzle movement speed (+MS1): the number of substrate rotation RS1: the discharge flow rate FL2) until the upper-surface processing nozzles 51F reach the switching position P3, and at the switching position P3, the operating condition is switched to the second operating condition (=the nozzle movement speed (+MS1): the number of substrate rotation RS2: the discharge flow rate FL1). Thus, during a period while the upper-surface processing nozzles 51F are moved through above the end surface of the substrate W and above the notch NT to the switching position P3, i.e., in the first half of the outward side bevel processing (timings T2 to T3), the cut-arrival amount is suppressed to be low, and as a result, it is possible to reduce the amount of liquid splash occurring in the outward side bevel processing.

Further, in the return side bevel processing, the bevel processing is performed under the second operating condition (=the nozzle movement speed (−MS1): the number of substrate rotation RS2: the discharge flow rate FL1) until the upper-surface processing nozzles 51F reach the switching position P3, and from the switching position P3, the operating condition is switched to the first operating condition (=the nozzle movement speed (−MS1): the number of substrate rotation RS1: the discharge flow rate FL2). Then, during a period while the upper-surface processing nozzles 51F are moved through above the notch NT and above the end surface of the substrate W to the pre-dispense position P1, i.e., in the second half of the return side bevel processing (timings T5 to T6), the cut-arrival amount is suppressed to be low, and as a result, it is possible to reduce the amount of liquid splash occurring in the return side bevel processing.

Thus, also in the fifth embodiment, in each of the outward side bevel processing and the return side bevel processing, the first operating condition and the second operating condition are switched in accordance with the switching position P3 (=the notch position P4). As a result, like in the first embodiment to the fourth embodiment, it is possible to effectively suppress occurrence of particles by preventing or suppressing occurrence of the liquid splash caused by the notch NT.

### The Sixth Embodiment

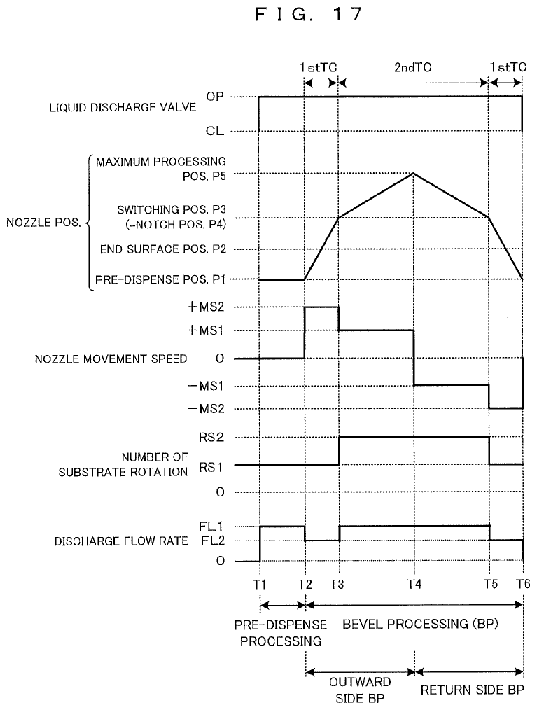

FIG. 16 is a timing chart of the pre-dispense processing and the bevel processing performed in the sixth embodiment of the substrate processing apparatus according to the present invention. In this sixth embodiment, the change in the nozzle movement speed made in the second embodiment and the change in the discharge flow rate made in the third embodiment are combined. Specifically, in the outward side bevel processing and the return side bevel processing, the following switching of the operating conditions is performed.

In the outward side bevel processing, the bevel processing is performed under the first operating condition (=the nozzle movement speed (+MS2): the number of substrate rotation RS2: the discharge flow rate FL2) until the upper-surface processing nozzles 51F reach the switching position P3, and at the switching position P3, the operating condition is switched to the second operating condition (=the nozzle movement speed (+MS1): the number of substrate rotation RS2: the discharge flow rate FL1). Thus, during a period while the upper-surface processing nozzles 51F are moved through above the end surface of the substrate W and above the notch NT to the switching position P3, i.e., in the first half of the outward side bevel processing (timings T2 to T3), the cut-arrival amount is suppressed to be low, and as a result, it is possible to reduce the amount of liquid splash occurring in the outward side bevel processing.

Further, in the return side bevel processing, the bevel processing is performed under the second operating condition (=the nozzle movement speed (−MS1): the number of substrate rotation RS2: the discharge flow rate FL1) until the upper-surface processing nozzles 51F reach the switching position P3, and from the switching position P3, the operating condition is switched to the first operating condition (=the nozzle movement speed (−MS2): the number of substrate rotation RS2: the discharge flow rate FL2). Then, during a period while the upper-surface processing nozzles 51F are moved through above the notch NT and above the end surface of the substrate W to the pre-dispense position P1, i.e., in the second half of the return side bevel processing (timings T5 to T6), the cut-arrival amount is suppressed to be low, and as a result, it is possible to reduce the amount of liquid splash occurring in the return side bevel processing.

Thus, also in the sixth embodiment, in each of the outward side bevel processing and the return side bevel processing, the first operating condition and the second operating condition are switched in accordance with the switching position P3 (=the notch position P4). As a result, like in the first embodiment to the fifth embodiment, it is possible to effectively suppress occurrence of particles by preventing or suppressing occurrence of the liquid splash caused by the notch NT.

### The Seventh Embodiment

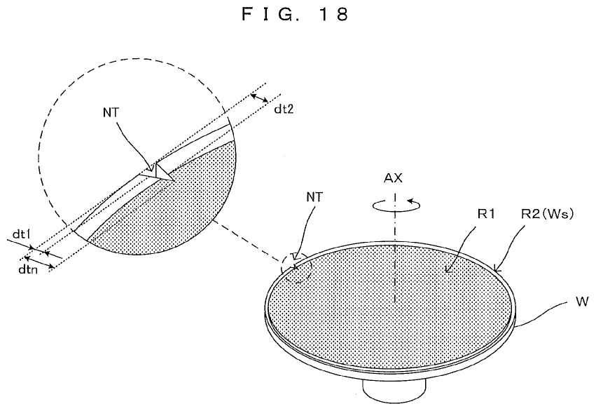

FIG. 17 is a timing chart of the pre-dispense processing and the bevel processing performed in the seventh embodiment of the substrate processing apparatus according to the present invention. In this seventh embodiment, the change in the number of substrate rotation made in the first embodiment, the change in the nozzle movement speed made in the second embodiment, and the change in the discharge flow rate made in the third embodiment are combined. Specifically, in the outward side bevel processing and the return side bevel processing, the following switching of the operating conditions is performed.

In the outward side bevel processing, the bevel processing is performed under the first operating condition (=the nozzle movement speed (+MS2): the number of substrate rotation RS1: the discharge flow rate FL2) until the upper-surface processing nozzles 51F reach the switching position P3, and at the switching position P3, the operating condition is switched to the second operating condition (=the nozzle movement speed (+MS1): the number of substrate rotation RS2: the discharge flow rate FL1). Thus, during a period while the upper-surface processing nozzles 51F are moved through above the end surface of the substrate W and above the notch NT to the switching position P3, i.e., in the first half of the outward side bevel processing (timings T2 to T3), the cut-arrival amount is suppressed to be low, and as a result, it is possible to reduce the amount of liquid splash occurring in the outward side bevel processing.

Further, in the return side bevel processing, the bevel processing is performed under the second operating condition (=the nozzle movement speed (−MS1): the number of substrate rotation RS2: the discharge flow rate FL1) until the upper-surface processing nozzles 51F reach the switching position P3, and from the switching position P3, the operating condition is switched to the first operating condition (=the nozzle movement speed (−MS2): the number of substrate rotation RS1: the discharge flow rate FL2). Then, during a period while the upper-surface processing nozzles 51F are moved through above the notch NT and above the end surface of the substrate W to the pre-dispense position P1, i.e., in the second half of the return side bevel processing (timings T5 to T6), the cut-arrival amount is suppressed to be low, and as a result, it is possible to reduce the amount of liquid splash occurring in the return side bevel processing.

Thus, also in the seventh embodiment, in each of the outward side bevel processing and the return side bevel processing, the first operating condition and the second operating condition are switched in accordance with the switching position P3 (=the notch position P4). As a result, like in the first embodiment to the sixth embodiment, it is possible to effectively suppress occurrence of particles by preventing or suppressing occurrence of the liquid splash caused by the notch NT.

Further, the present invention is not limited to the above-described embodiments, and various changes can be made to the aforementioned ones without departing from the gist of the present invention. For example, in the above-described embodiments, as shown in FIG. 10, though the case where the distance dtn is not longer than the width dt2 to which the bevel processing should be performed has been described, the first embodiment to the seventh embodiment can be basically applied also to, for example, a case where the distance dtn is not shorter than the width dt2 to which the bevel processing should be performed, as shown in FIG. 18. It is necessary, however, to set the switching position P3 so that (dt1)<(dt2) may be satisfied. Specifically, it is necessary to set the switching position P3 which corresponds to an “intermediate position” of the present invention, between the end surface position P2 and the maximum processing position P5.

Further, in the above-described embodiments, as the control items affecting the cut-arrival amount, the number of substrate rotation, the nozzle movement speed, and the discharge flow rate of the selected processing liquid are adopted and at least one of these items is switched at the switching position P3. The control items include, for example, an exhaust flow rate from the exhaust part 38 other than those items. Specifically, in the outward side bevel processing, the exhaust flow rate is increased until the upper-surface processing nozzles 51F reach the switching position P3, and on the other hand, after that, the exhaust flow rate may be returned to that suitable for the bevel processing. Furthermore, in the return side bevel processing, the exhaust flow rate is set to that suitable for the bevel processing until the upper-surface processing nozzles 51F reach the switching position P3, and on the other hand, during a period while the upper-surface processing nozzles 51F are moved through above the notch NT and above the end surface of the substrate W and returned to the pre-dispense position P1, the exhaust flow rate may be increased. By changing the operating conditions at the switching position P3 thus, like in the first embodiment to the seventh embodiment, it is possible to effectively suppress occurrence of particles by preventing or suppressing occurrence of the liquid splash caused by the notch NT. Further, though the bevel processing is performed on the peripheral edge part Ws of the substrate W by using the three types of processing liquids in the above-described embodiments, the type of processing liquid is not limited to these types.

Further, though the present invention is applied to the substrate processing apparatus which rotates the rotating cup 31 in synchronization with the substrate W in the above-described embodiments, the rotation of the cup is not essential, and the present invention can be also applied to a substrate processing apparatus which does not rotate the cup as disclosed in JP 6980457B2.

Further, though the substrate W provided with a substantially V-shaped or substantially U-shaped notch NT at the peripheral edge part thereof is an object to be processed in the above-described embodiments, a substrate provided with a cut having a shape other than those shapes is also an object of the present invention.

Further, though the return side bevel processing is performed immediately after the outward movement is completed in the above-described embodiments, there may be a case where the upper-surface processing nozzles are paused at the maximum processing position P5 after the outward movement is completed and then the return movement is performed. After the outward movement is completed, for example, at the maximum processing position P5, the second operating condition is maintained on the number of substrate rotation and the discharge flow rate while the nozzle movement speed is made zero. Then, after the processing is performed for a certain time at the maximum processing position P5, the return movement may be performed.

Although the present invention has been described with reference to specific embodiments, this description is not meant to be construed in a limiting sense. Various modifications of the disclosed embodiment, as well as other embodiments of the present invention, will become apparent to persons skilled in the art upon reference to the description of the present invention. It is therefore contemplated that the appended claims will cover any such modifications or embodiments as fall within the true scope of the present invention.

This invention is applicable to a substrate processing technique in general for processing a substrate provided with a cut such as a notch or the like at a peripheral edge part thereof by supplying a processing liquid to the peripheral edge part of the substrate while rotating the substrate.

What is claimed is:

1. A substrate processing apparatus, comprising:
a substrate holder configured to hold a substrate provided with a cut at part of a peripheral edge part thereof in a horizontal posture, being rotatable about an axis of rotation;
a rotating part configured to rotate the substrate holder about the axis of rotation;
a processing liquid supplier having a nozzle to discharge a processing liquid so as to supply the processing liquid to the peripheral edge part of the substrate;
a nozzle mover configured to move the nozzle in a radial direction of the substrate; and
a controller configured to control an operating condition of the rotating part, the processing liquid supplier and the nozzle mover so as to cause the nozzle to make an outward movement from the outside of the substrate through an end surface of the substrate to a maximum processing position and then make a return movement in a direction reverse to the outward movement while rotating the substrate and discharging the processing liquid from the nozzle, the maximum processing position being away from the end surface toward a center of the substrate by a predetermined bevel processing distance,
wherein assuming that the amount of processing liquid discharged from the nozzle arrives at the cut per unit time during the nozzle movement is a cut-arrival amount and that a midpoint between the end surface and the maximum processing position in the radial direction of the substrate is an intermediate position,
the controller is configured to switch the operating condition of at least one of the rotating part, the processing liquid supplier, and the nozzle mover at the intermediate position so that the cut-arrival amount during the nozzle movement between the end surface and the intermediate position becomes lower than the cut-arrival amount during the nozzle movement between the intermediate position and the maximum processing position.

2. The substrate processing apparatus according to claim 1, wherein
when the distance from the end surface of the substrate to a deepest position of the cut in the radial direction is shorter than the bevel processing distance,
the intermediate position is set between the deepest position and the maximum processing position in the radial direction of the substrate.

3. The substrate processing apparatus according to claim 2, wherein
the intermediate position coincides with the deepest position.

4. The substrate processing apparatus according to claim 1, wherein
when the distance from the end surface of the substrate to a deepest position of the cut is equal to or longer than the bevel processing distance,
the intermediate position is set between the position of the end surface and the maximum processing position in the radial direction of the substrate.

5. The substrate processing apparatus according to claim 1, wherein
the operating condition includes the number of rotation of the substrate,
the controller is configured to control so that an outward side bevel processing and a return side bevel processing are performed in this order, the outward side bevel processing being a process in which the nozzle is moved outward from the outside of the substrate through the end surface of the substrate to the maximum processing position while rotating the substrate and discharging the processing liquid from the nozzle, the return side bevel processing being a process in which the nozzle is moved backward from the maximum processing position to the outside of the substrate while rotating the substrate and discharging the processing liquid from the nozzle,
to control the rotating part in the outward side bevel processing so that the number of rotation during a first outward movement from the outside of the substrate to the intermediate position is smaller than the number of rotation during a second outward movement from the intermediate position to the maximum processing position, and
to control the rotating part in the return side bevel processing so that the number of rotation during a first return movement from the intermediate position to the outside of the substrate is smaller than the number of rotation during a second return movement from the maximum processing position to the intermediate position.

6. The substrate processing apparatus according to claim 5, wherein
the operating condition includes a movement speed of the nozzle in the radial direction of the substrate, and
the controller is configured to control the nozzle mover so that a movement speed during the first outward movement is higher than a movement speed during the second outward movement and a movement speed during the first return movement is higher than a movement speed during the second return movement.

7. The substrate processing apparatus according to claim 6, wherein
the operating condition includes a discharge flow rate of the processing liquid to be discharged from the nozzle, and
the controller is configured to control the processing liquid supplier so that a discharge flow rate during the first outward movement is lower than a discharge flow rate during the second outward movement and a discharge flow rate during the first return movement is lower than a discharge flow rate during the second return movement.

8. The substrate processing apparatus according to claim 1, wherein
the operating condition includes a movement speed of the nozzle in the radial direction of the substrate, and
the controller is configured to control so that an outward side bevel processing and a return side bevel processing are performed in this order, the outward side bevel processing being a process in which the nozzle is moved outward from the outside of the substrate through the end surface of the substrate to the maximum processing position while rotating the substrate and discharging the processing liquid from the nozzle, the return side bevel processing being a process in which the nozzle is moved backward from the maximum processing position to the outside of the substrate while rotating the substrate and discharging the processing liquid from the nozzle,
to control the nozzle mover in the outward side bevel processing so that a movement speed during a first outward movement from the outside of the substrate to the intermediate position is higher than a movement speed during a second outward movement from the intermediate position to the maximum processing position, and
to control the nozzle mover in the return side bevel processing so that a movement speed during a first return movement from the intermediate position to the outside of the substrate is higher than a movement speed during a second return movement from the maximum processing position to the intermediate position.

9. The substrate processing apparatus according to claim 8, wherein
the operating condition includes a discharge flow rate of the processing liquid to be discharged from the nozzle, and
the controller is configured to control the processing liquid supplier so that a discharge flow rate during the first outward movement is lower than a discharge flow rate during the second outward movement and a discharge flow rate during the first return movement is lower than a discharge flow rate during the second return movement.

10. The substrate processing apparatus according to claim 1, wherein
the operating condition includes a discharge flow rate of the processing liquid to be discharged from the nozzle, and
the controller is configured to control so that an outward side bevel processing and a return side bevel processing are performed in this order, the outward side bevel processing being a process in which the nozzle is moved outward from the outside of the substrate through the end surface of the substrate to the maximum processing position while rotating the substrate and discharging the processing liquid from the nozzle, the return side bevel processing being a process in which the nozzle is moved backward from the maximum processing position to the outside of the substrate while rotating the substrate and discharging the processing liquid from the nozzle,
to control the processing liquid supplier in the outward side bevel processing so that a discharge flow rate during a first outward movement from the outside of the substrate to the intermediate position is lower than a discharge flow rate during a second outward movement from the intermediate position to the maximum processing position, and
to control the processing liquid supplier in the return side bevel processing so that a discharge flow rate during a first return movement from the outside of the substrate to the intermediate position is lower than a discharge flow rate during a second outward movement from the intermediate position to the maximum processing position.

11. A substrate processing method, comprising:
(a) rotating a substrate provided with a cut at part of a peripheral edge part thereof in a horizontal posture about an axis of rotation;
(b) causing a nozzle to make an outward movement from the outside of the substrate where the nozzle is being rotated, through an end surface of the substrate to a maximum processing position away from the end surface by a predetermined bevel processing distance while discharging a processing liquid from the nozzle; and
(c) causing the nozzle to make a return movement in a direction reverse to the outward movement while keeping rotation of the substrate and discharging the processing liquid from the nozzle after the operation (b)
wherein assuming that the amount of processing liquid which is discharged from the nozzle during movement of the nozzle and arrives at the cut per unit time is a cut-arrival amount and that a midpoint between the end surface and the maximum processing position in a radial direction of the substrate is an intermediate position,
an operating condition on at least one of rotation of the substrate, discharge of the processing liquid, and movement of the nozzle is switched at the intermediate position so that the cut-arrival amount during the movement of the nozzle between the end surface and the intermediate position is lower than the cut-arrival amount during the movement of the nozzle between the intermediate position and the maximum processing position both in the operation (b) and the operation (c).
